(19) United States
(12) Patent Application Publication
(10) Pub. No.: US 2026/0247891 A1
(43) Pub. Date: Aug. 20, 2026

(54) SUBSTRATE PROCESSING METHOD

(71) Applicant: Tokyo Electron Limited, Tokyo (JP)

(72) Inventors: Rintaro HIGUCHI, Kumamoto (JP); Koji KAGAWA, Kumamoto (JP)

(73) Assignee: Tokyo Electron Limited, Tokyo (JP)

(21) Appl. No.: 19/159,349

(22) PCT Filed: Feb. 29, 2024
(86) PCT No.: PCT/JP2024/007549

§ 371 Date: Aug. 25, 2025

(30) Foreign Application Priority Data
Mar. 6, 2023 (JP) 2023-033561

(51) Int. Cl. H10P 50/68; H10P 70/00

(52) U.S. Cl. CPC H10P 50/683; H10P 70/23

(57) ABSTRACT

A substrate processing method includes an etching step that supplies an etching liquid to a substrate with a SiCN film that is formed thereon to etch the SiCN film. The etching step supplies a mixed liquid of hydrofluoric acid and an oxidant as the etching liquid to the substrate.

### FIELD

A disclosed embodiment(s) relate(s) to a substrate processing method.

### BACKGROUND

A technique to etch a SiN (silicon nitride) film that is formed on a substrate such as a semiconductor wafer (that will also be referred to as a wafer below) with an etching liquid of phosphoric acid has been known conventionally (see Patent Literature 1).

### CITATION LIST

### Patent Literature

Japanese Patent Application Publication No. 2018-060896

### SUMMARY

### Technical Problem

The present disclosure provides a technique that is capable of etching a SiCN film that is formed on a substrate efficiently.

### Solution to Problem

A substrate processing method according to an aspect of the present disclosure includes an etching step that supplies an etching liquid to a substrate with a SiCN film that is formed thereon to etch the SiCN film. The etching step supplies a mixed liquid of hydrofluoric acid and an oxidant as the etching liquid to the substrate.

### Advantageous Effects of Invention

According to the present disclosure, it is possible to etch a SiCN film that is formed on a substrate efficiently.

### BRIEF DESCRIPTION OF DRAWINGS

FIG. 1 is a schematic diagram that illustrates a general configuration of a substrate processing system according to an embodiment.

FIG. 2 is a schematic diagram that illustrates an example of a specific configuration of a processing unit according to an embodiment.

FIG. 3 is a flowchart that illustrates an example of a procedure of substrate processing that is executed by a substrate processing system according to an embodiment.

FIG. 4 is a diagram that illustrates an etching rate for a SiCN film in a case where an etching process is executed with various types of etching liquids.

FIG. 5 is a diagram that illustrates a relationship between a mixing ratio of hydrofluoric acid and nitric acid in an etching liquid and an etching rate for a SiCN film.

FIG. 6 is a diagram that illustrates a relationship between a mixing ratio of hydrofluoric acid and potassium permanganate in an etching liquid and an etching rate for a SiCN film.

### DESCRIPTION OF EMBODIMENTS

Hereinafter, an embodiment(s) of a substrate processing method as disclosed in the present application will be explained in detail with reference to the accompanying drawing(s). Additionally, the present disclosure is not limited by an embodiment(s) as illustrated below. Furthermore, it has to be noted that a drawing(s) is/are schematic where a relationship(s) between dimensions of respective elements, a ratio(s) of respective elements, etc., may differ from reality. Moreover, parts where relationships between dimensions and/or ratios are different from one another may also be included in mutual drawings.

A technique to etch a SiN (silicon nitride) film that is formed on a substrate such as a semiconductor wafer (that will also be referred to as a wafer below) with an etching liquid of phosphoric acid has been known conventionally. Furthermore, changing a SiN film that is used for a semiconductor element such as a FinFET (Fin Field-Effect Transistor) to a SiCN (silicon carbonitride) film is studied currently.

However, a SiCN film is very dense and hard as compared with a SiN film, so that an etching rate for such a SiCN film is very small with phosphoric acid and/or hydrofluoric acid that is/are conventionally used as an etching liquid for such a SiCN film. That is, in a conventional technique, it is very difficult to etch a SiCN film that is formed on a substrate efficiently.

Hence, realization of a technique that is capable of overcoming a problem(s) as described above and etching a SiCN film that is formed on a substrate efficiently is expected.

### <Outline of Substrate Processing System>

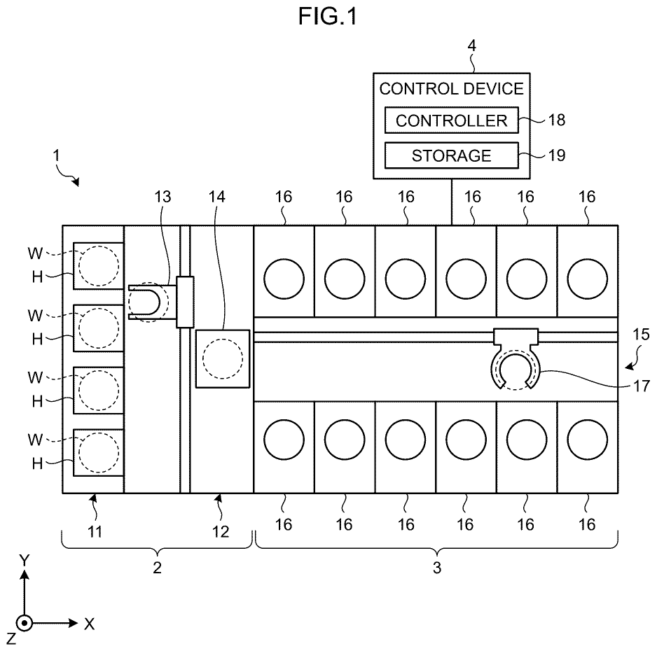

First, a general configuration of a substrate processing system 1 according to an embodiment will be explained with reference to FIG. 1. FIG. 1 is a diagram that illustrates a general configuration of a substrate processing system 1 according to an embodiment. Hereinafter, an X-axis, a Y-axis, and a Z-axis that are orthogonal to one another are specified and a positive direction of such a Z-axis is provided as a vertically upward direction, so as to clarify a positional relationship.

As illustrated in FIG. 1, the substrate processing system 1 includes a carrying-in/out station and a processing station 3. The carrying-in/out station 2 and the processing station 3 are provided adjacently.

The carrying-in/out station 2 includes a hoop placing section 11 and a transfer section 12. In the hoop placing section 11, a plurality of hoops H that house a plurality of substrates, in an embodiment, semiconductor wafers W (that will be referred to as wafers W below) in horizontal states thereof are placed.

The transfer section 12 is provided so as to be adjacent to the hoop placing section 11 and includes a substrate transfer device 13 and a delivery unit 14 in an inside thereof. The substrate transfer device 13 includes a wafer holding mechanism that holds a wafer W. Furthermore, the substrate transfer device 13 is capable of moving in a horizontal direction and a vertical direction and turning around a vertical axis as a center thereof and executes transfer of a wafer W between a hoop H and the delivery unit 14 by using a wafer holding mechanism.

The processing station 3 is provided so as to be adjacent to the transfer section 12. The processing station 3 includes a transfer section 15 and a plurality of processing units 16. The plurality of processing units 16 are provided side by side on both sides of the transfer section 15.

The transfer section 15 includes a substrate transfer device 17 in an inside thereof. The substrate transfer device 17 includes a wafer holding mechanism that holds a wafer W. Furthermore, the substrate transfer device 17 is capable of moving in a horizontal direction and a vertical direction and turning around a vertical axis as a center thereof and executes transfer of a wafer W between the delivery unit 14 and a processing unit 16 by using a wafer holding mechanism.

A processing unit 16 executes predetermined substrate processing for a wafer W that is transferred by the substrate transfer device 17.

Furthermore, the substrate processing system 1 includes a control device 4. The control device 4 is, for example, a computer and includes a controller 18 and a storage 19. The storage 19 stores therein a program that controls various types of processes that are executed in the substrate processing system 1. The controller 18 reads and executes a program that is stored in the storage 19, so as to control an operation of the substrate processing system 1.

Additionally, such a program may be recorded in a computer-readable storage medium and be installed in the storage 19 of the control device 4 from such a storage medium. For a computer-readable storage medium, for example, a hard disk (HD), a flexible disk (FD), a compact disk (CD), a magnetooptical disk (MO), a memory card, etc., are provided.

In the substrate processing system 1 that is configured as described above, first, the substrate transfer device 13 of the carrying-in/out station 2 takes a wafer W from a hoop H that is placed in the hoop placing section 11 and places such a taken wafer W on the delivery unit 14. A wafer W that is placed on the delivery unit 14 is taken from the delivery unit 14 and is carried in a processing unit 16, by the substrate transfer device 17 of the processing station 3.

A wafer W that is carried in a processing unit 16 is processed by such a processing unit 16, subsequently carried out of such processing unit 16, and placed on the delivery unit 14, by the substrate transfer device 17. Then, a processed wafer W that is placed on the delivery unit 14 is returned to a hoop H of the hoop placing section 11 by the substrate transfer device 13.

### <Configuration of Processing Unit>

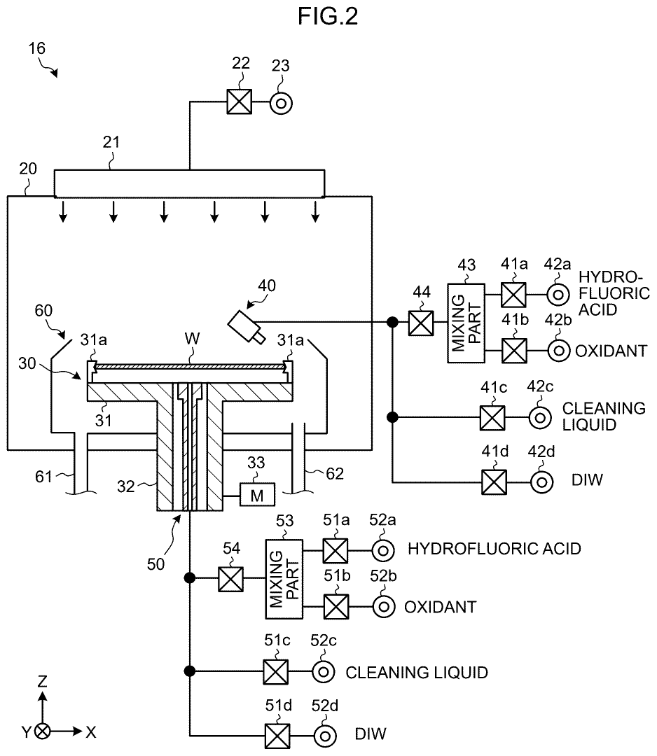

Next, a configuration of a processing unit 16 according to an embodiment will be explained with reference to FIG. 2. FIG. 2 is a schematic diagram that illustrates an example of a specific configuration of a processing unit 16. As illustrated in FIG. 2, the processing unit 16 includes a chamber 20, a substrate processing part 30, a peripheral part supply part 40, a back surface supply part 50, and a recovery cup 60.

The chamber 20 houses the substrate processing part 30, the peripheral part supply part 40, the back surface supply part 50, and the recovery cup 60. On a ceiling part of the chamber 20, an FFU (Fan Filter Unit) 21 is provided. The FFU 21 forms a downflow in the chamber 20.

The FFU 21 is connected to a downflow gas supply source 23 through a flow rate regulator 22. The FFU 21 discharges a downflow gas (for example, nitrogen or dry air, etc.) that is supplied from the downflow gas supply source 23 to an inside of the chamber 20. The flow rate regulator 22 regulates a flow rate of a downflow gas that is supplied to the FFU 21. The flow rate regulator 22 has an opening/closing valve, a flow rate control valve, and a flowmeter, etc.

The substrate processing part 30 includes a holding part 31, a supporting part 32, and a driving part 33 and applies predetermined substrate processing to a placed wafer W. The holding part 31 holds a wafer W horizontally. On an upper surface of the holding part 31, a plurality of gripping parts 31a that grip a peripheral part of a wafer W are provided.

A wafer W is held horizontally by such gripping parts 31a in a state where it is slightly separated from an upper surface of the holding part 31. Additionally, a wafer W is held by the holding part 31 in a state where a surface where various types of semiconductor devices, etc., are formed is oriented in an upward direction.

The supporting part 32 is a member that extends in a vertical direction and supports the holding part 31 from below. The driving part 33 rotates the supporting part 32 around a vertical axis.

The substrate processing part 30 rotates the supporting part 32 by using the driving part 33, so as to rotate the holding part 31 that is supported by the supporting part 32, and thereby, rotate a wafer W that is held by the holding part 31.

The peripheral part supply part 40 supplies various types of processing liquids to a peripheral part of a wafer W that is held by the substrate processing part 30. The peripheral part supply part 40 is connected to a mixing part 43 through a flow rate regulator 44. The mixing part 43 is connected to a hydrofluoric acid supply source 42a through a flow rate regulator 41a and is connected to an oxidant supply source 42b through a flow rate regulator 41b.

The hydrofluoric acid supply source 42a is, for example, a tank that stores a stock solution of hydrofluoric acid (HF) (at a concentration of, for example, 50 (wt %)). The flow rate regulator 41a regulates a flow rate of hydrofluoric acid that is supplied to the mixing part 43. The flow rate regulator 41a has an opening/closing valve, a flow rate control valve, and a flowmeter, etc.

The oxidant supply source 42b is, for example, a tank that stores a stock solution of an oxidant. The flow rate regulator 41b regulates a flow rate of an oxidant that is supplied to the mixing part 43. The flow rate regulator 41b has an opening/closing valve, a flow rate control valve, and a flowmeter, etc.

An oxidant according to an embodiment includes, for example, at least one of potassium permanganate, nitric acid, phosphoric acid, an aqueous solution of hydrogen peroxide, peracetic acid, perchloric acid, ammonium peroxodisulfate, orthoperiodic acid, and ozone water.

The mixing part 43 mixes hydrofluoric acid that is supplied from the hydrofluoric acid supply source 42a and an oxidant that is supplied from the oxidant supply source 42b so as to produce an etching liquid. The flow rate regulator 44 regulates a flow rate of an etching liquid that is supplied from the mixing part 43 to the peripheral part supply part 40. The flow rate regulator 44 has an opening/closing valve, a flow rate control valve, and a flowmeter, etc.

Furthermore, the peripheral part supply part 40 is connected to a cleaning liquid supply source 42c through a flow rate regulator 41c. The cleaning liquid supply source 42c is, for example, a tank that stores a cleaning liquid. The flow rate regulator 41c regulates a flow rate of a cleaning liquid that is supplied to the peripheral part supply part 40. The flow rate regulator 41c has an opening/closing valve, a flow rate control valve, and a flowmeter, etc.

A cleaning liquid according to an embodiment includes, for example, at least one of an acidic hydrofluoric acid, a SC2 (a mixed liquid of hydrochloric acid, hydrogen peroxide, and water), and alkaline SC1 (a mixed liquid of ammonia, hydrogen peroxide, and water).

Furthermore, the peripheral part supply part 40 is connected to a DIW supply source 42d through a flow rate regulator 41d. The DIW supply source 42d is, for example, a tank that stores DIW (DeIonized Water: deionized water). The flow rate regulator 41d regulates a flow rate of DIW that is supplied to the peripheral part supply part 40. The flow rate regulator 41d has an opening/closing valve, a flow rate control valve, and a flowmeter, etc. Such DIW is used for, for example, a rinsing process for a wafer W.

The back surface supply part 50 supplies various types of processing liquids to a back surface of a wafer W that is held by the substrate processing part 30. The back surface supply part 50 is inserted through a hollow part of the holding part 31 and the supporting part 32. Inside the back surface supply part 50, a flow channel that extends in a vertical direction is formed.

Such a flow channel is connected to a mixing part 53 through a flow rate regulator 54. The mixing part 53 is connected to a hydrofluoric acid supply source 52a through a flow rate regulator 51a and is connected to an oxidant supply source 52b through a flow rate regulator 51b.

The hydrofluoric acid supply source 52a is, for example, a tank that stores a stock solution of hydrofluoric acid (at a concentration of, for example, 50 (wt %)). The flow rate regulator 51a regulates a flow rate of hydrofluoric acid that is supplied to the mixing part 53. The flow rate regulator 51a has an opening/closing valve, a flow rate control valve, and a flowmeter, etc.

The oxidant supply source 52b is, for example, a tank that stores a stock solution of an oxidant. The flow rate regulator 51b regulates a flow rate of an oxidant that is supplied to the mixing part 53. The flow rate regulator 51b has an opening/closing valve, a flow rate control valve, and a flowmeter, etc.

The mixing part 53 mixes hydrofluoric acid that is supplied from the hydrofluoric acid supply source 52a and an oxidant that is supplied from the oxidant supply source 52b so as to produce an etching liquid. The flow rate regulator 54 regulates a flow rate of an etching liquid that is supplied from the mixing part 53 to the back surface supply part 50. The flow rate regulator 54 has an opening/closing valve, a flow rate control valve, and a flowmeter, etc.

Furthermore, a flow channel that is formed inside the back surface supply part 50 is connected to a cleaning liquid supply source 52c through a flow rate regulator 51c. The cleaning liquid supply source 52c is, for example, a tank that stores a cleaning liquid. The flow rate regulator 51c regulates a flow rate of a cleaning liquid that is supplied to the back surface supply part 50. The flow rate regulator 51c has an opening/closing valve, a flow rate control valve, and a flowmeter, etc.

Furthermore, a flow channel that is formed inside the back surface supply part 50 is connected to a DIW supply source 52d through a flow rate regulator 51d. The DIW supply source 52d is, for example, a tank that stores DIW. The flow rate regulator 51d regulates a flow rate of DIW that is supplied to the back surface supply part 50. The flow rate regulator 51d has an opening/closing valve, a flow rate control valve, and a flowmeter, etc.

The recovery cup 60 is arranged so as to surround the holding part 31 and collects a processing liquid that is scattered from a wafer W due to rotation of the holding part 31. On a bottom part of the recovery cup 60, a drain port 61 is formed where a processing liquid that is collected by the recovery cup 60 is discharged from such a drain port 61 to an outside of the processing unit 16. Furthermore, on a bottom part of the recovery cup 60, an exhaust port 62 is formed that discharges a gas that is supplied from the FFU 21 to an outside of the processing unit 16.

### <Detail of Substrate Processing>

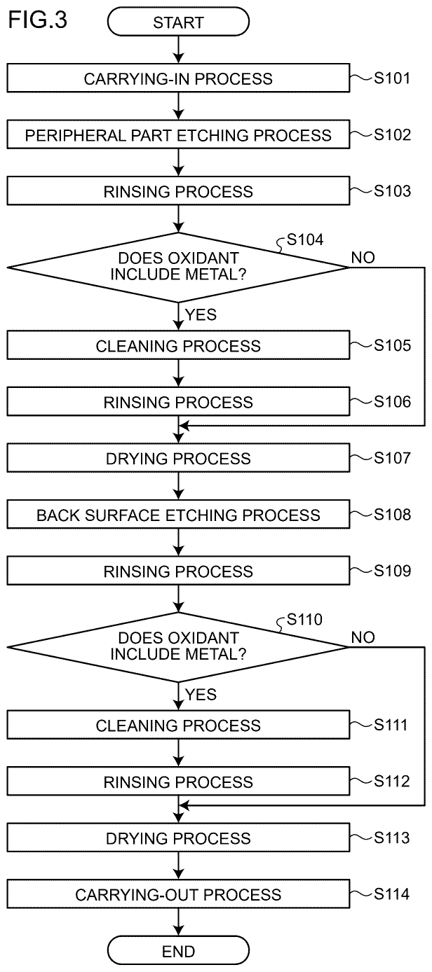

Next, a detail of substrate processing according to an embodiment will be explained with reference to FIG. 3 to FIG. 6. FIG. 3 is a flow chart that illustrates an example of a procedure of substrate processing that is executed by a substrate processing system 1 according to an embodiment.

In substrate processing according to an embodiment, first, a controller 18 controls transfer sections 12, 15, etc., so as to carry a wafer W in a processing unit 16 (step S101). Such a wafer W is held by a holding part 31 in a state where various types of semiconductor devices that include a SiCN film are formed. That is, in an embodiment, a SiCN film is formed on a wafer W.

Then, the controller 18 controls a peripheral part supply part 40, etc., so as to execute a peripheral part etching process that etches a SiCN film that is formed on a peripheral part among a SiCN film that is formed on a wafer W (step S102).

Herein, in an embodiment, it is preferable to execute an etching process for a SiCN film with an etching liquid that is produced by mixing hydrofluoric acid and an oxidant. Thereby, it is possible to etch a SiCN film that is formed on a peripheral part of a wafer W efficiently. A reason thereof will be explained below.

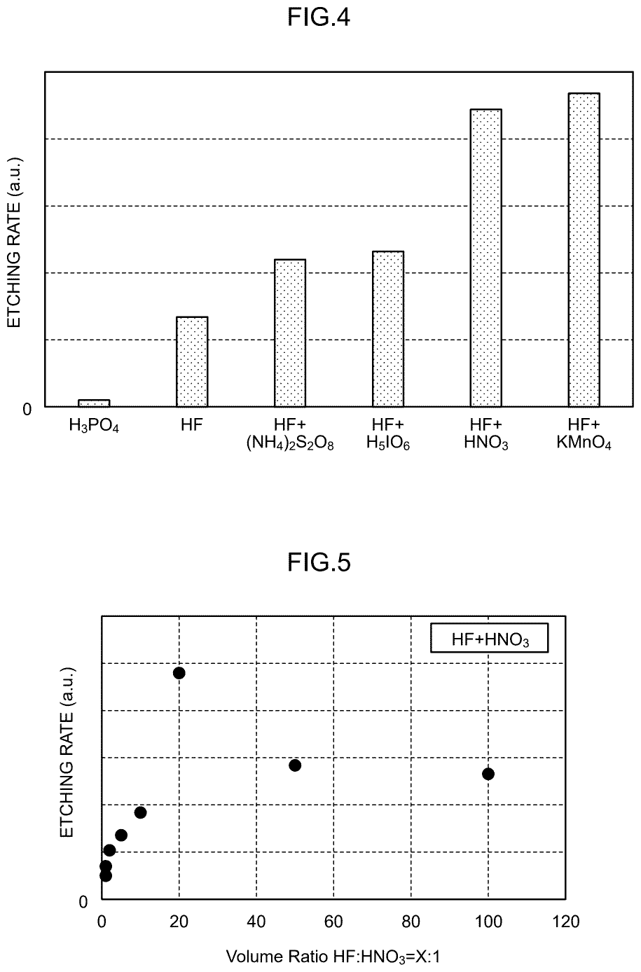

FIG. 4 is a diagram that illustrates an etching rate of a SiCN film in a case where an etching process is executed with various types of etching liquids. Additionally, FIG. 4 also illustrates data of only stock solutions of phosphoric acid (H₃PO₄) (at a concentration of 85 (wt %)) and hydrofluoric acid (HF) (at 50 (wt %)) that are used for a conventional etching process for a SiCN film, as reference examples.

FIG. 4 illustrates data in a case where ammonium peroxodisulfate ((NH₄)₂S₂O₈), orthoperiodic acid (H₅IO₆), nitric acid (HNO₃), and potassium permanganate (KMnO₄) are used as oxidants that compose an etching liquid according to an embodiment. In a result of an experiment as illustrated in FIG. 4, a temperature of an etching liquid of phosphoric acid is 160 (° C.) and temperatures of other etching liquids are 50 (° C.).

In a result of an experiment as illustrated in FIG. 4, for an etching liquid where ammonium peroxodisulfate is used as an oxidant, a stock solution of hydrofluoric acid (at 50 (wt %)) and a stock solution of ammonium peroxodisulfate (at 0.5 (wt %)) are mixed at a volume ratio of 10:1.

In a result of an experiment as illustrated in FIG. 4, for an etching liquid where orthoperiodic acid is used as an oxidant, a stock solution of hydrofluoric acid (at 50 (wt %)) and a stock solution of orthoperiodic acid (at 37 (wt %)) are mixed at a volume ratio of 10:1.

In a result of an experiment as illustrated in FIG. 4, for an etching liquid where nitric acid is used as an oxidant, a stock solution of hydrofluoric acid (at 50 (wt %)) and a stock solution of nitric acid (at 69 (wt %)) are mixed at a volume ratio of 20:1.

In a result of an experiment as illustrated in FIG. 4, for an etching liquid where potassium permanganate is used as an oxidant, a stock solution of hydrofluoric acid (at 50 (wt %)) and a stock solution of potassium permanganate (at 0.3 (wt %)) are mixed at a volume ratio of 20:1.

As illustrated in FIG. 4, in an embodiment, an oxidant is added to hydrofluoric acid, so that an etching rate for a SiCN film is improved as compared with a case where conventional etching with only phosphoric acid or hydrofluoric acid is executed. It is considered that this is because chemical reaction as represented by formula (1) as provided below is caused during an etching process so as to accelerate etching for an SiCN film.

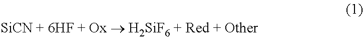

Ox: an oxidant
Red: a reduced form of an oxidant
Other: a by-product (such as water or a salt)

For example, in a case where an oxidant is nitric acid, it is considered that an etching process is accelerated due to chemical reaction as represented by formula (2) as provided below.

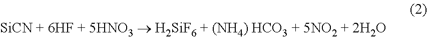

Furthermore, in a case where an oxidant is potassium permanganate, it is considered that an etching process is accelerated due to chemical reaction as represented by formula (3) as provided below.

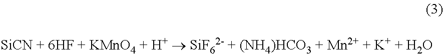

Thus, in an embodiment, a mixed liquid of hydrofluoric acid and an oxidant is used as an etching liquid, so that it is possible to etch a SiCN film that is formed on a wafer W efficiently.

Furthermore, it is preferable for an oxidant according to an embodiment to include at least one of KMnO₄, HNO₃, H₃PO₄, H₂O₂, C₂H₄O₃, HClO₄, (HN₄)₂S₂O₈, H₅IO₆, and ozone water, and it is more preferable to include at least one of KMnO₄ and HNO₃. Thereby, it is possible to etch a SiCN film that is formed on a wafer W more efficiently.

Additionally, an oxidant that is provided as a raw material of an etching liquid in the present disclosure is not limited to a case it is an oxidant as described above, and various kinds of oxidants may be used. Thereby, chemical reaction as represented by formula (1) as described above is also caused during an etching process, so that etching for a SiCN film is accelerated.

FIG. 5 is a diagram that illustrates a relationship between a mixing ratio of hydrofluoric acid and nitric acid in an etching liquid and an etching rate for a SiCN film. Additionally, a graph as illustrated in FIG. 5 is a result of an experiment in a case where a volume X of a stock solution of hydrofluoric acid is provided on a horizontal axis thereof in a case where a volume of a stock solution of nitric acid is provided as 1.

As illustrated in FIG. 5, for an etching liquid where hydrofluoric acid and nitric acid are mixed, it is found that an etching rate is changed depending on a mixing ratio thereof and such an etching rate is provided as a curve that has a local maximum point near a volume ratio of hydrofluoric acid and nitric acid=20:1.

It is considered that this is because fluoric acid and nitric acid are present inside an etching liquid without excess or deficiency for one another so that chemical reaction as represented by formula (2) is caused most efficiently.

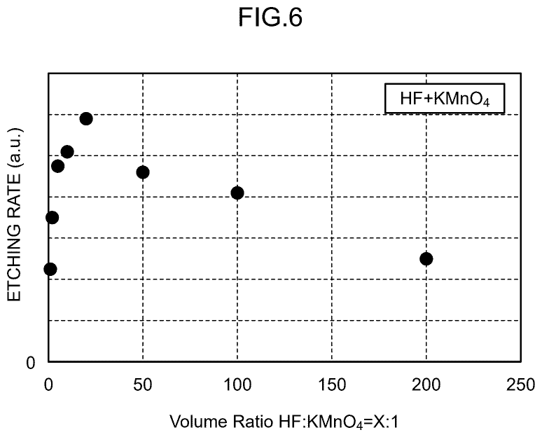

FIG. 6 is diagram that illustrates a relationship between a mixing ratio of hydrofluoric acid and potassium permanganate in an etching liquid and an etching rate for a SiCN film. Additionally, a graph as illustrated in FIG. 6 is a result of an experiment in a case where a volume X of a stock solution of hydrofluoric acid is provided on a horizontal axis thereof in a case where a volume of a stock solution of potassium permanganate is provided as 1.

As illustrated in FIG. 6, for an etching liquid where hydrofluoric acid and potassium permanganate are mixed, it is found that an etching rate is changed depending on a mixing ratio thereof and such an etching rate is provided as a curve that has a local maximum point near a volume ratio of hydrofluoric acid and potassium permanganate=20:1.

It is considered that this is because fluoric acid and potassium permanganate are present inside an etching liquid without excess or deficiency for one another so that chemical reaction as represented by formula (3) is caused most efficiently.

As thus far explained, it is preferable to mix an oxidant at a volume ratio within a range of 0.001 to 1 per 1 of hydrofluoric acid in an etching liquid according to an embodiment, and it is more preferable to mix it at a volume ratio within a range of 0.01 to 0.1 per 1 of hydrofluoric acid. Thereby, it is possible to etch a SiCN film that is formed on a wafer W more efficiently.

Furthermore, in an embodiment, hydrofluoric acid that is a raw material of an etching liquid is not limited to a case where it is provided as a stock solution and a concentration of hydrofluoric acid may be 5 (wt %) to 50 (wt %). Thus, hydrofluoric acid that is provided as a raw material is also useable as being other than a stock solution, so that it is possible to reduce a manufacturing cost of an etching liquid.

Additionally, in a case where hydrofluoric acid other than a stock solution is used as a raw material of an etching liquid, a concentration and a mixing ratio of an oxidant is appropriately adjustable based on a good range of a mixing ratio in such a stock solution.

Furthermore, in an embodiment, in a case where ozone water is used as an oxidant, it is preferable to provide a concentration of such ozone water that is 100 (ppm) or less. Thus, ozone water with a concentration in a range where it is readily manufactured is useable, so that it is possible to reduce a manufacturing cost of an etching liquid.

Furthermore, in an embodiment, it is preferable to provide a temperature of an etching liquid that is 20 (° C.) to 80 (° C.). Thereby, it is possible to etch a SiCN film that is formed on a wafer W more efficiently.

An explanation for FIG. 3 will be continued. Subsequent to a peripheral part etching process, the controller 18 controls the peripheral part supply part 40, etc., so as to discharge DIW to a peripheral part of a wafer W where an etching process has been executed, and thus, execute a rinsing process for such a peripheral part of a wafer W (step S103).

Then, the controller 18 determines whether or not an oxidant that is used for an etching liquid includes a metal in a peripheral part etching process at step S102 (step S104).

Then, in a case where it is determined that an oxidant includes a metal (step S104, Yes), the controller 18 controls the peripheral part supply part 40, etc., so as to discharge a cleaning liquid to a peripheral part of a wafer W where an etching process has been executed, and thus, execute a cleaning process for such a peripheral part of a wafer W (step S105).

For example, in a case where potassium permanganate is used for an oxidant, the controller 18 determines that such an oxidant includes a metal (in such a case, potassium and manganese).

Then, the controller 18 controls the peripheral part supply part 40, etc., so as to discharge DIW to a peripheral part of a wafer W where a cleaning process has been executed, and thus, execute a rinsing process for such a peripheral part of a wafer W (step S106).

Additionally, in a case where it is determined that an oxidant does not include a metal (step S104, No) in a process at step S104, the controller 18 transfers to a process at step S107 as described later.

Thus, in substrate processing according to an embodiment, in a case where an oxidant includes a metal, a cleaning process that removes such a metal from a wafer W is executed, so that it is possible to provide a wafer W where an etching process for a SiCN film has been executed, in a clean state thereof.

Furthermore, in an embodiment, it is preferable for a cleaning liquid to include at least one of hydrofluoric acid, SC2, and SC1. Thereby, it is possible to remove a metal that remains on a wafer W after an etching process efficiently.

Furthermore, in an embodiment, in a case where hydrofluoric acid is used for a cleaning liquid, it is preferable to provide such hydrofluoric acid at a concentration that is 0.5 (wt %) to 25 (wt %) and a temperature that is 20 (° C.) to 80 (° C.). Thereby, it is possible to remove a metal that remains on a wafer W after an etching process more efficiently.

Furthermore, in an embodiment, in a case where SC2 is used for a cleaning liquid, it is preferable to provide such SC2 at a mixing ratio that is HCl:H₂O₂:H₂O=1:1:100 to 1:1:10 and a temperature that is 20 (° C.) to 80 (° C.). Thereby, it is possible to remove a metal that remains on a wafer W after an etching process more efficiently.

Furthermore, in an embodiment, in a case where SC1 is used for a cleaning liquid, it is preferable to provide such SC1 at a mixing ratio that is NH₄OH:H₂O₂:H₂O=1:1:100 to 1:1:10 and a temperature that is 20 (° C.) to 80 (° C.). Thereby, it is possible to remove a metal that remains on a wafer W after an etching process more efficiently.

An explanation for FIG. 3 will be continued. Subsequent to a process at step S106, the controller 18 controls a substrate processing part 30, etc., so as to execute a drying process that is executed by spin-drying for a wafer W (step S107).

Then, the controller 18 controls a back surface supply part 50, etc., so as to execute a back surface etching process that etches a SiCN film that is formed on a back surface, among a SiCN film that is formed on a wafer W (step S108).

In such a back surface etching process, an etching process for a back surface of a wafer W is executed by using an etching liquid where hydrofluoric acid and an oxidant are mixed, similarly to a peripheral part etching process as described above. Thereby, it is possible to etch a SiCN film that is formed on a back surface of a wafer W efficiently. Additionally, a detail of an etching liquid is similar to that of a peripheral part etching process as described above, so that a detailed explanation thereof will be omitted.

Then, the controller 18 controls the back surface supply part 50, etc., so as to discharge DIW to a back surface of a wafer W where an etching process has been executed, and thus, executes a rinsing process for such a back surface of a wafer W (step S109).

Then, the controller 18 determines whether or not an oxidant that is used for an etching liquid includes a metal in a back surface etching process at step S108 (step S110).

Then, in a case where it is determined that an oxidant includes a metal (step S110, Yes), the controller 18 controls the back surface supply part 50, etc., so as to discharge a cleaning liquid to a back surface of a wafer W where an etching process has been executed, and thus, executes a cleaning process for such a back surface of a wafer W (step S111).

Then, the controller 18 controls the back surface supply part 50, etc., so as to discharge DIW to a back surface of a wafer W where a cleaning process has been executed, and thus, executes a rinsing process for such a back surface of a wafer W (step S112). Then, the controller 18 controls the substrate processing part 30, etc., so as to execute a drying process that is executed by spin-drying for a wafer W (step S113).

Finally, the controller 18 controls the transfer sections 12, 15, etc., so as to carry a wafer W out of the processing unit 16 (step S114), and ends a series of substrate processing.

Additionally, in a process at step S110, in a case where it is determined that an oxidant does not include a metal (step S110, No), the controller 18 transfers to a process at step S113.

As thus far explained, in substrate processing according to an embodiment, it is preferable to execute an etching process for SiCN films that are formed on a peripheral part and a back surface of a wafer W by using the peripheral part supply part 40 and the back surface supply part 50. Thereby, it is possible to etch SiCN films that are formed on a peripheral part and a back surface of a wafer W efficiently.

Additionally, although an example where an etching process is executed for both of SiCN films that are formed on a peripheral part and a back surface of a wafer W has been illustrated in an example of FIG. 3, the present disclosure is not limited to such an example and such an etching process may be executed one of such a peripheral part and a back surface of a wafer W.

Furthermore, an etching process may be executed for a SiCN film that is formed on a site other than a peripheral part of a front surface of a wafer W by using a technique according to the present disclosure. Thereby, it is possible to etch a SiCN film that is formed on a site other than a peripheral part of a front surface of a wafer W efficiently.

Moreover, an etching process may collectively be executed for a plurality of wafers W in such a manner that an etching liquid where hydrofluoric acid and an oxidant are mixed is stored in a processing tank and such a plurality of wafers W are collectively dipped in such a processing tank, by using a technique according to the present disclosure.

Thereby, it is possible to execute a rework process for a plurality of wafers W efficiently, for example, when such a rework process is executed for a SiCN film that is formed on a wafer W.

A substrate processing method according to an embodiment includes an etching step (step S102, S108) that supplies an etching liquid to a substrate (a wafer W) where a SiCN film is formed, so as to etch a SiCN film. An etching step (step S102, S108) supplies a mixed liquid of hydrofluoric acid and an oxidant to a substrate (a wafer W) as an etching liquid. Thereby, it is possible to etch a SiCN film that is formed on a wafer W efficiently.

Furthermore, in a substrate processing method according to an embodiment, an oxidant includes at least one of potassium permanganate, nitric acid, phosphoric acid, an aqueous solution of hydrogen peroxide, peracetic acid, perchloric acid, ammonium peroxodisulfate, orthoperiodic acid, and ozone water. Thereby, it is possible to etch a SiCN film that is formed on a wafer W more efficiently.

Furthermore, in a substrate processing method according to an embodiment, an oxidant is mixed at a volume ratio within a range of 0.001 to 1 per 1 of hydrofluoric acid. Thereby, it is possible to etch a SiCN film that is formed on a wafer W more efficiently.

Furthermore, in a substrate processing method according to an embodiment, an oxidant is mixed at a volume ratio within a range of 0.01 to 0.1 per 1 of hydrofluoric acid. It is possible to etch a SiCN film that is formed on a wafer W more efficiently.

Furthermore, in a substrate processing method according to an embodiment, a concentration of hydrofluoric acid that is provided as a raw material of an etching liquid is 5 (wt %) to 50 (wt %). Thereby, it is possible to reduce a manufacturing cost of an etching liquid.

Furthermore, in a substrate processing method according to an embodiment, a concentration of ozone water that is used as an oxidant is 100 (ppm) or less. Thereby, it is possible to reduce a manufacturing cost of an etching liquid.

Furthermore, in a substrate processing method according to an embodiment, a temperature of an etching liquid is 20 (° C.) to 80 (° C.). Thereby, it is possible to etch a SiCN film that is formed on a wafer W more efficiently.

Furthermore, in a substrate processing method according to an embodiment, an etching step (step S102, S108) etches a SiCN film that is formed on at least one of a peripheral part and a back surface of a substrate (a wafer W). Thereby, it is possible to etch a SiCN film that is formed on a peripheral part and a back surface of a wafer W efficiently.

Furthermore, a substrate processing method according to an embodiment further includes a cleaning step (step S105, S111) that cleans a substrate (a wafer W) with at least one of an acidic cleaning liquid and a SC1 cleaning liquid, after an etching step (step S102, S108). Thereby, it is possible to provide a wafer W where an etching process for a SiCN film has been executed, in a clean state thereof.

Furthermore, in a substrate processing method according to an embodiment, an acidic cleaning liquid is at least one of hydrofluoric acid and SC2. Thereby, it is possible to remove a metal that remains on a wafer W after an etching process efficiently.

Furthermore, in a substrate processing method according to an embodiment, hydrofluoric acid that is used as an acidic cleaning liquid is provided at a concentration that is 0.5 (wt %) to 25 (wt %) and a temperature that is 20 (° C.) to 80 (° C.). Thereby, it is possible to remove a metal that remains on a wafer W after an etching process more efficiently.

Furthermore, in a substrate processing method according to an embodiment, SC2 that is used as an acidic cleaning liquid is provided at a mixing ratio that is HCl:H₂O₂:H₂O=1:1:100 to 1:1:10 and a temperature that is 20 (° C.) to 80 (° C.). Thereby, it is possible to remove a metal that remains on a wafer W after an etching process more efficiently.

Furthermore, in a substrate processing method according to an embodiment, an SC1 cleaning liquid is provided at a mixing ratio that is NH₄OH:H₂O₂:H₂O=1:1:100 to 1:1:10 and a temperature that is 20 (° C.) to 80 (° C.). Thereby, it is possible to remove a metal that remains on a wafer W after an etching process more efficiently.

Although an embodiment(s) of the present disclosure has/have been explained above, the present disclosure is not limited to an embodiment(s) as described above and it is possible to execute a variety of modifications thereon without departing from an essence(s) thereof.

It should be considered that an embodiment(s) that is/are disclosed herein is/are not limitative but be illustrative in all aspects thereof. In fact, it is possible to implement an embodiment(s) as described above in a variety of forms thereof. Furthermore, an embodiment(s) as described above may be omitted, substituted, and/or modified in various forms thereof, without departing from an attached claim(s) and an essence(s) thereof.

### REFERENCE SIGNS LIST

W wafer (an example of a substrate)
1 substrate processing system
16 processing unit
30 substrate processing part
40 peripheral part supply part
50 back surface supply part

1. A substrate processing method, comprising
supplying an etching liquid to a substrate with a SiCN film that is formed thereon to etch the SiCN film, wherein
the supplying includes supplying a mixed liquid of hydrofluoric acid and an oxidant as the etching liquid to the substrate.

2. The substrate processing method according to claim 1, wherein
the oxidant includes at least one of potassium permanganate, nitric acid, phosphoric acid, an aqueous solution of hydrogen peroxide, peracetic acid, perchloric acid, ammonium peroxodisulfate, orthoperiodic acid, and ozone water.

3. The substrate processing method according to claim 2, wherein
the oxidant is mixed at a volume ratio within a range of 0.001 to 1 per 1 of hydrofluoric acid.

4. The substrate processing method according to claim 2, wherein
the oxidant is mixed at a volume ratio within a range of 0.01 to 0.1 per 1 of hydrofluoric acid.

5. The substrate processing method according to claim 1, wherein
a concentration of hydrofluoric acid that is provided as a raw material of the etching liquid is 5 wt % to 50 wt %.

6. The substrate processing method according to claim 2, wherein
a concentration of ozone water that is used as the oxidant is 100 ppm or less.

7. The substrate processing method according to claim 1, wherein
a temperature of the etching liquid is 20° C. to 80° C.

8. The substrate processing method according to claim 1, wherein
the supplying includes etching the SiCN film that is formed on at least one of a peripheral part and back surface of the substrate.

9. The substrate processing method according to claim 1, further comprising
cleaning the substrate with at least one of an acidic cleaning liquid and a SC1 cleaning liquid, after the supplying.

10. The substrate processing method according to claim 9, wherein
the acidic cleaning liquid is at least one of hydrofluoric acid and SC2.

11. The substrate processing method according to claim 10, wherein
hydrofluoric acid that is used as the acidic cleaning liquid is provided at a concentration that is 0.5 wt % to 25 wt % and a temperature that is 20° C. to 80° C.

12. The substrate processing method according to claim 10, wherein
SC2 that is used as the acidic cleaning liquid is provided at a mixing ratio that is HCl:H₂O₂:H₂O=1:1:100 to 1:1:10 and a temperature that is 20° C. to 80° C.

13. The substrate processing method according to claim 9, wherein
the SC1 cleaning liquid is provided at a mixing ratio that is NH₄OH:H₂O₂:H₂O=1:1:100 to 1:1:10 and a temperature that is 20° C. to 80° C.
